(19) United States
(12) Patent Application Publication
(10) Pub. No.: US 2010/0003111 A1
(43) Pub. Date: Jan. 7, 2010

(54) SUBSTRATE PROCESSING APPARATUS AND METHOD FOR TRANSFERRING SUBSTRATE FOR THE APPARATUS

(75) Inventors: Young Koo Yeo, Chungcheongnam-do (KR); Jin Young Choi, Chungcheongnam-do (KR); Tae Ho Kim, Chungcheongnam-do (KR)

Correspondence Address: CARTER, DELUCA, FARRELL & SCHMIDT, LLP, 445 BROAD HOLLOW ROAD, SUITE 420, MELVILLE, NY, 11747, US

(73) Assignee: SEMES CO., Ltd., Chungcheongnam-do (KR)

(21) Appl. No.: 12/498,093

(22) Filed: Jul. 6, 2009

(30) Foreign Application Priority Data
Jul. 7, 2008 (KR) 2008-65641

(51) Int. Cl. H01L 21/677

(52) U.S. Cl. 414/222.07; 414/222.01; 414/806

(57) ABSTRACT

A substrate processing apparatus includes a main load unit, a buffer load unit, and a distribution unit. The main load unit is disposed at a front side of the process module for receiving a plurality of containers each accommodating substrates. The buffer load unit receives a plurality of containers, and the distribution unit transfers a container between the main load unit and the buffer load unit. The substrate processing apparatus includes the buffer load unit as well as the main load unit, and the distribution unit is used to transfer a container between the main load unit and the buffer load unit. Therefore, substrates can be transferred to the substrate processing apparatus with less time, and thus productivity can be improved.

### CROSS-REFERENCE TO RELATED APPLICATIONS

This U.S. non-provisional patent application claims priority under 35 U.S.C. §119 of Korean Patent Application No. 10-2008-0065641, filed on Jul. 7, 2008, the entire contents of which are hereby incorporated by reference.

### BACKGROUND OF THE INVENTION

The present invention disclosed herein relates to a substrate processing apparatus, and more particularly, to a substrate processing apparatus and a method for transferring a substrate for the substrate processing apparatus.

In a substrate manufacturing method, processes such as deposition of dielectric films and metallic materials, etching, coating with photoresist, developing, and ashing are repeated for a predetermined number of times so as to forming arrays of fine patterns. Although an etching or ashing process is performed during such substrate manufacturing processes, foreign substances are not completely removed from a substrate but remain on the substrate. For this reason, a wet cleaning process may be performed using deionized water or chemicals so as to remove such remaining substances.

Substrate cleaning apparatuses for wet cleaning may be classified into batch substrate cleaning apparatus and single substrate cleaning apparatus. A batch substrate cleaning apparatus may include a chemical bath, a rinse bath, and a dry bath that are sized to process about 25 to 50 substrates at a time. In a batch substrate cleaning apparatus processor, substrates are immersed in each bath for a predetermined time for removing foreign substances from the substrates. In such a batch substrate cleaning apparatus, both the front and rear sides of a large number of substrates can be simultaneously processed. However, since the sizes of baths of a batch substrate cleaning apparatus is proportional to the size of substrates, the size and chemical consumption of the batch substrate cleaning apparatus increases as the size of substrates increases. Moreover, when a substrate is cleaned in a chemical bath, foreign substances detached from a neighboring substrate can be re-attached to the substrate.

Since the sizes of recently-used substrates are large, single substrate cleaning apparatus is widely used. In the case of a single substrate cleaning apparatus, a substrate cleaning process is performed in a relatively small chamber capable of processing only a single substrate at a time. Specifically, in a single substrate cleaning apparatus, a substrate is fixed to a chuck disposed in a chamber, and chemical or deionized water is supplied to the top surface of the substrate through a nozzle while rotating the substrate using a motor. Since the substrate is rotated, the chemical or deionized water can spread on the substrate, and foreign substances are removed from the substrate by the spreading chemical or deionized water. Such a single processor is relatively small and suitable for uniformly cleaning a substrate as compared with a batch processor.

Generally, a single processor includes a plurality of load ports, an index robot, a buffer unit, a plurality of process chambers, and a main transfer robot that are arranged from a side of the single substrate cleaning apparatus. Front opening unified pods (FOUPs) accommodating substrates are placed on the load ports, respectively. The index robot carries the substrates accommodated in the FOUP to the buffer unit, and the main transfer robot transfers the substrates from the buffer unit to the process chambers. After the substrates are cleaned in the process chambers, the main transfer robot carries the substrates from the process chambers to the buffer unit, and the index robot takes the substrates from the buffer unit and puts the substrates into the FOUP. After the cleaned substrates are accommodated in the FOUP as described, the FOUP is carried to the outside.

Generally, a FOUP is transferred by an overhead hoist transport (OHT). In detail, the OHT transfers a FOUP accommodating uncleaned substrates to an empty load port, and the OHT picks up a FOUP accommodating cleaned substrates from the load ports and transfers the FOUP to an outside area.

Since such an OHT is operated with a low speed, it takes more time to transfer a FOUP using the OHT than to draw uncleaned substrates from the FOUP and put cleaned substrates into the FOUP. Moreover, the time necessary for cleaning substrates is shortened because the efficiency of a cleaning apparatus is improved owing to the development of related technology; however, the speed of OHT is still low. Therefore, FOUPs cannot be efficiently transferred by using an OHT, thereby increasing the idle time of a cleaning apparatus and decreasing the productivity of a manufacturing process.

### SUMMARY OF THE INVENTION

The present invention provides a substrate processing apparatus having improved substrate transferring efficiency.

The present invention also provides a method for transferring a substrate for the substrate processing apparatus.

Embodiments of the present invention provide substrate processing apparatuses include a process module, a main load unit, a buffer load unit, and a distribution unit.

The process module is configured to process a substrate. The main load unit is disposed at a front side of the process module for receiving a plurality of containers each accommodating a plurality of substrates, and the main load unit is configured so that substrates are transferred between the containers placed on the main load unit and the process module. The buffer load unit is configured to receive a plurality of containers. The distribution unit is disposed above the main load unit for transferring a container between the main load unit and the buffer load unit.

In other embodiments of the present invention, substrate processing apparatuses include a process module, a plurality of load ports, a plurality of buffer ports, a distribution unit, and an overhead hoist transport unit.

The process module is configured to process a substrate. The load ports are disposed at a front side of the process module in parallel with each other for receiving containers each accommodating substrates, and the load ports are configured so that substrates are transferred between the containers placed on the load ports and the process module. The buffer ports are disposed directly above the load ports, and each of the buffer ports faces one of the load ports and is configured to receive a container and move horizontally into and out of the process module. The distribution unit is disposed above the buffer ports and movable horizontally in a direction along which the load ports are arranged, so as to transfer a container between the buffer ports and the load ports. The overhead hoist transport unit is configured to transfer a container between an outside area and the buffer ports.

In still other embodiments of the present invention, substrate processing apparatuses include a process module, a plurality of load ports, a plurality of buffer ports, a distribution unit, and an overhead hoist transport unit.

The process module is configured to process a substrate. The load ports are disposed at a front side of the process module in parallel with each other for receiving containers each accommodating substrates, and the load ports are configured so that substrates are transferred between the containers placed on the load ports and the process module. The buffer ports face the process module with the load ports being disposed between the buffer ports and the process module, and each of the buffer ports faces one of the load ports and is configured to receive a container. The distribution unit is disposed above the load ports. The distribution unit is configured to move horizontally in a first direction along which the load ports are arranged and move horizontally above the load ports and the buffer ports in a second direction perpendicular to the first direction, so as to transfer a container between the buffer ports and the load ports. The overhead hoist transport unit is configured to transfer a container between an outside area and the buffer ports.

In even other embodiments of the present invention, there are provided methods for transferring a substrate. In the method, a container accommodating unprocessed substrates is transferred from an outside area to an empty buffer port of a plurality of buffer ports. A container accommodating unprocessed substrates is picked up from the buffer ports and is placed on an empty load port of a plurality of load ports so as to load the unprocessed substrates contained in the container to a process module for processing the unprocessed substrates. A container accommodating processed substrates is picked up from the load ports and is transferred to an empty buffer port of the buffer ports. A distribution unit disposed above the load ports is used to transfer a container between the buffer ports and the load ports, and an overhead hoist transport unit is used to transfer a container accommodating unprocessed substrates from the outside area to an empty buffer port of the buffer ports and transfer a container accommodating processed substrates to the outside area.

In yet other embodiments of the present invention, there are provided methods for transferring a substrate. In the method, a container accommodating unprocessed substrates is transferred from an outside area to a buffer load unit. A container accommodating unprocessed substrates is transferred from the buffer load unit to a main load unit so as to load the unprocessed substrates contained in the container to a process module for processing the substrates. A container accommodating processed substrates is transferred from the main load unit to the buffer load unit. A container accommodating processed substrates is transferred from the buffer load unit to the outside area.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a partial perspective view illustrating a substrate processing apparatus according to an embodiment of the present invention;

FIG. 2 is a sectional view illustrating the substrate processing apparatus of FIG. 1;

FIGS. 3A through 3D are views for explaining how substrates are transferred in the substrate processing apparatus of FIG. 2;

FIG. 4 is a partial perspective view illustrating a substrate processing apparatus according to another embodiment of the present invention;

FIG. 5 is a section view illustrating the substrate processing apparatus of FIG. 5;

FIG. 6 is a partial perspective view illustrating a main container of the substrate processing apparatus of FIG. 5; and

FIGS. 7A through 7C are views for explaining how substrates are transferred in the substrate processing apparatus of FIG. 4.

### DETAILED DESCRIPTION OF PREFERRED EMBODIMENTS

Preferred embodiments of the present invention will be described below in more detail with reference to the accompanying drawings. In the following description, wafers are described as examples of substrates. However, the scope and spirit of the present invention are not limited thereto.

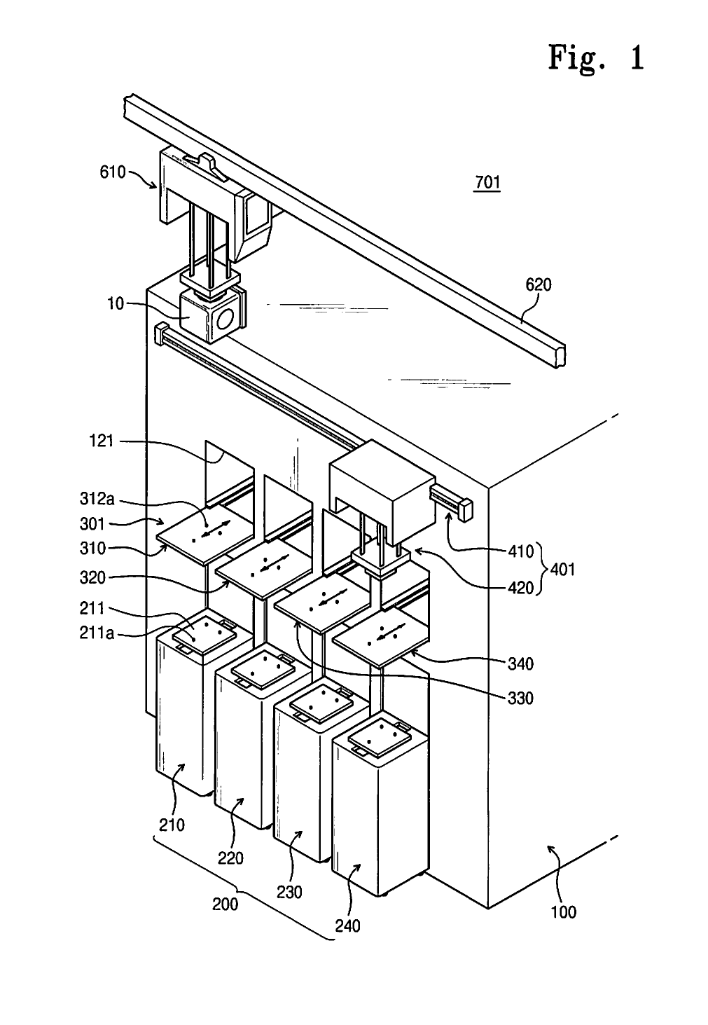

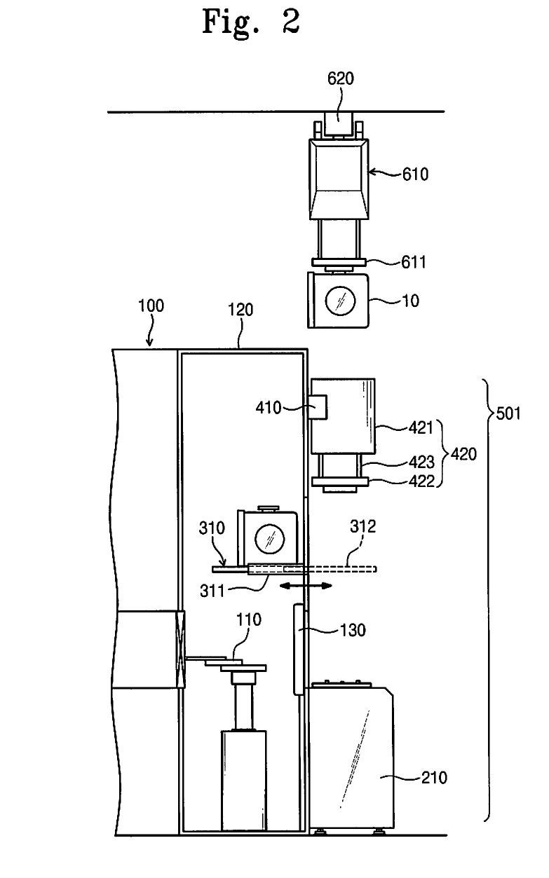

FIG. 1 is a partial perspective view illustrating a substrate processing apparatus 701 according to an embodiment of the present invention, and FIG. 2 is a sectional view illustrating the substrate processing apparatus 701 of FIG. 1.

Referring to FIGS. 1 and 2, the substrate processing apparatus 701 of the current embodiment includes a process module 100 and a substrate supply module 501. The process module 100 is configured to process wafers, and the substrate supply module 501 is configured to supply wafers (unprocessed wafers) to the process module 100 for processing the wafers and carry the wafers to the outside after the wafers are processed.

In detail, unprocessed wafers are supplied to the substrate processing apparatus 701 in a state where the unprocessed wafers are accommodated in a front opening unified pod (FOUP) 10, and after the unprocessed wafers are processed, the processed wafers are carried out of the substrate processing apparatus 701 in a state where the processed wafers are accommodated in the FOUP 10.

In the current embodiment, the substrate processing apparatus 701 uses the FOUP 10 as a container for carrying wafers. However, instead of the FOUP 10, other containers can be used for carrying wafers.

The process module 100 may include an index robot 110 configured to pick up unprocessed wafers from the FOUP 10 carried to the substrate supply module 501. Unprocessed wafers picked up by the index robot 110 are supplied to a plurality of process chambers (not shown) for processing the wafers. In the process chambers, a processing process such as a cleaning process may be performed. After the wafers are processed, the index robot 110 loads the processed wafers back to the FOUP 10 disposed at the substrate supply module 501. That is, after the wafers are processed, the wafers are carried out of the process chambers, and the index robot 110 transfers and loads the processed wafers back to the FOUP 10.

The substrate supply module 501 is disposed at the front side of the process module 100 for supplying wafers to the process module 100 in a state where the wafers are accommodated in the FOUP 10.

In detail, the substrate supply module 501 may include a main load unit 200, a buffer load unit 301, and a distribution unit 401.

The main load unit 200 is disposed at the front side of the process module 100 and makes contact with the process module 100. The main load unit 200 includes a plurality of load ports 210 to 240, and a FOUP 10 can be placed on each of the load ports 210 to 240.

In the current embodiment, the main load unit 200 includes four load ports 210 to 240. However, the number of load ports 210 to 240 can be increased or decreased for the processing efficiency of the substrate processing apparatus 701.

The load ports 210 to 240 are disposed at a sidewall of a partition bay 120 in which components of the process module 100 are disposed, and a plurality of door openers 130 corresponding to the load ports 210 to 240 are disposed at the partition bay 120. The door openers 130 are used to open doors of FOUPs 10 placed on the corresponding load ports 210 to 240.

The load ports 210 to 240 are arranged in parallel with each other along the floor. Each of the load ports 210 to 240 may include a sliding plate 211 disposed at a predetermined surface for supporting a FOUP 10. The sliding plate 211 can be moved horizontally to adjust the horizontal position of a FOUP 10 placed on its top surface.

That is, when a FOUP 10 is placed on one of the load ports 210 to 240, the sliding plate 211 of the load port is moved horizontally and forwardly to place the FOUP 10 onto the door opener 130, and then the door openers 130 opens a door of the FOUP 10. After the door of the FOUP 10 is opened, the index robot 110 takes wafers out of the opened FOUP 10.

Thereafter, processed wafers are put into the opened FOUP 10, and the door openers 130 closes the door of the FOUP 10. The sliding plate 211 is moved horizontally and backward to move FOUP 10 horizontally.

Fixing protrusions 211a may be disposed on the top surface of the sliding plate 211 for fixing a FOUP 10 placed on the sliding plate 211. The fixing protrusions 21 la may be coupled to a FOUP 10 placed on the sliding plate 211 for fixing the FOUP 10 to the sliding plate 211.

The buffer load unit 301 is disposed above the main load unit 200, and a plurality of FOUPs 10 can be placed on the buffer load unit 301.

In detail, the buffer load unit 301 includes a plurality of buffer ports 310 to 340. In an embodiment, the number of the buffer ports 310 to 340 is equal to the number of the load ports 210 to 240, and the positions of the buffer ports 310 to 340 correspond to the positions of the load ports 210 to 240, respectively. However, the number of the buffer ports 310 to 340 can be increased or decreased for the processing efficiency of the substrate processing apparatus 701.

The buffer ports 310 to 340 are arranged in the same direction as the load ports 210 to 240 in a manner such that the buffer ports 310 to 340 face the corresponding load ports 210 to 240, respectively.

The buffer ports 310 to 340 can be horizontally moved into and out of the process module 100. In detail, each of the buffer ports 310 to 340 may include a guide rail 311 disposed inside the process module 100, and a stage 312 configured to receive a FOUP 10. The guide rail 311 is disposed at an inner wall of the partition bay 120 in a manner such that the guide rail 311 extends perpendicularly from the inner wall of the partition bay 120 and faces a bottom surface of the partition bay 120 at a position above the index robot 110.

The stage 312 is connected to the guide rail 311. The stage 312 may include a plurality of protrusions 312a for fixing a FOUP 10. The protrusions 312a extend from the top surface of the stage 312 for coupling with a FOUP 10 placed on the top surface of the stage 312 to fix the FOUP 10 to the stage 312. Insertion holes (not shown) are formed in the bottom surface of the FOUP 10 for receiving the protrusions 312a.

The stage 312 can be horizontally moved along the guide rail 311 into the partition bay 120 and out of the partition bay 120. A plurality of inlet/outlet holes 121 corresponding to the buffer ports 310 to 340 are formed at the partition bay 120. The inlet/outlet holes 121 are formed at positions corresponding to the buffer ports 310 to 340, respectively, and each of the inlet/outlet holes 121 is sized so that the stage 312 can be moved through the inlet/outlet hole 121 together with a FOUP 10. The stage 312 can be taken into the process module 100 and out of the process module 100 by horizontally moving the stage 312.

In the current embodiment, the buffer ports 310 to 340 of the buffer load unit 301 can be horizontally moved independent of each other.

The distribution unit 401 is disposed above the buffer load unit 301. The distribution unit 401 can be horizontally moved along the arranged load ports 210 to 240. The distribution unit 401 is used to transfer a FOUP 10 between the buffer load unit 301 and the main load unit 200.

In detail, the distribution unit 401 may include a transfer rail 410 and a pickup part 420. The transfer rail 410 extends along the arranged load ports 210 to 240. In the current embodiment, the transfer rail 410 is disposed at an upper end position on a side of the partition bay 120. However, the transfer rail 410 can be installed separate from the partition bay 120.

The partition bay 120 may have a recessed part in which the distribution unit 401 is inserted by a length corresponding to the thickness of the guide rail 311, so as to prevent interference with an overhead hoist transport (OHT) 610.

The pickup part 420 is coupled to the transfer rail 410 and horizontally movable along the transfer rail 410. The pickup part 420 is used to pick up a FOUP 10 placed on one of the load ports 210 to 240 and the buffer ports 310 to 340.

In detail, the pickup part 420 may include a rail-movable part 421 coupled to the transfer rail 410 for being moved along the transfer rail 410, a fixer 422 configured to be detachably coupled to the top end of a FOUP 10 when the FOUP 10 is transferred, and a wire part 423 configured to adjust the vertical position of the fixer 422.

A side of the rail-movable part 421 is coupled to the transfer rail 410, and the rail-movable part 421 is movable along the transfer rail 410 for adjusting the horizontal position of the fixer 422. That is, the rail-movable part 421 is moved along the transfer rail 410 toward one of the load ports 210 to 240 and the buffer ports 310 to 340 where a FOUP 10 to be transferred is placed. Then, the pickup part 420 can be placed above the load port or buffer port. When the rail-movable part 421 is moved, the fixer 422 is kept at a predetermined height for preventing inference with FOUPs 10 placed on the main load unit 200.

An end of the wire part 423 is coupled to the fixer 422, and the other end of the wire part 423 is coupled to the rail-movable part 421. The length of the wire part 423 can be adjusted for lifting or lowering the fixer 422.

That is, when the pickup part 420 is placed above one of the load ports 210 to 240 and the buffer ports 310 to 340 on which a FOUP 10 to be transferred is placed, the fixer 422 is lowered by using the wire part 423 to place the fixer 422 on the top side of the FOUP 10. Then, the fixer 422 is coupled to the top side of the FOUP 10 for fixing the FOUP 10 to the pickup part 420. Thereafter, the fixer 422 is lifted by using the wire part 423 to a height where the FOUP 10 coupled to the fixer 422 does not make interference with other FOUPs 10 placed on the main load unit 200. The pickup part 420 to which the FOUP 10 is fixed is moved after the stages 312 of the buffer ports 310 to 340 are slid into the process module 100, so as to prevent interference between the pickup part 420 and the buffer ports 310 to 340.

The rail-movable part 421 is moved along the transfer rail 410 to a load port or a buffer port to which the FOUP 10 will be placed. Thereafter, the fixer 422 is lowered by the wire part 423 to place the FOUP 10 on the load port or the buffer port.

In the current embodiment, the fixer 422 is configured to be detachably coupled to the top side of a FOUP 10. However, the fixer 422 can be configured to be detachably coupled to a lateral side of a FOUP 10. Furthermore, instead of adjusting the vertical position of the fixer 422 of the pickup part 420 by using a wire, the vertical position of the fixer 422 may be adjusted by using a vertically movable arm or rail.

An equipment rail 620 is disposed above the buffer load unit 301 so that the OHT 610 can be moved on the equipment rail 620. Generally, the equipment rail 620 may be installed on the ceiling of a semiconductor manufacturing line where the substrate processing apparatus 701 is disposed. While moving along the equipment rail 620, the OHT 610 receives a FOUP 10 from another area and places the FOUP 10 on one of the buffer ports 310 to 340. In addition, the OHT 610 picks up a FOUP 10 placed on one of the buffer ports 310 to 340 and transfers the FOUP 10 to another area.

The OHT 610 includes a grip part 611 configured to be detachably coupled to a FOUP 10 to be transferred, and the vertical position of the grip part 611 is adjusted by using a wire.

As described above, the substrate processing apparatus 701 includes the buffer ports 310 to 340 as well as the load ports 210 to 240 for temporarily placing FOUPs 10 on the buffer ports 310 to 340 before the FOUPs 10 are transferred to a processing area. In addition, since the distribution unit 401 is used to transfer FOUPs 10 between the load ports 210 to 240 and the buffer ports 310 to 340, FOUPs 10 can be carried into and out of the substrate processing apparatus 701 with less influence by the transfer speed of the OHT 610.

Accordingly, the substrate processing apparatus 701 can have a reduced time for supplying FOUPs 10 to the process module 100 from a standby area. That is, equipment idle time can be reduced, and productivity can be improved.

Hereinafter, with reference to the accompanying drawings, detailed explains will be given on a process of transferring standby FOUPs in the substrate processing apparatus 701 and a process of transferring FOUPs to the outside of the substrate processing apparatus 701 after a processing process is finished. In the following explanations, the load ports 210 to 240 will be referred to as first to fourth load ports 210 to 240, and the buffer ports 310 to 340 will be referred to as first to fourth buffer ports 310 to 340. The first to fourth load ports 210 to 240 are sequentially arranged in the same direction, and the first to fourth buffer ports 310 to 340 are sequentially arranged in the same direction.

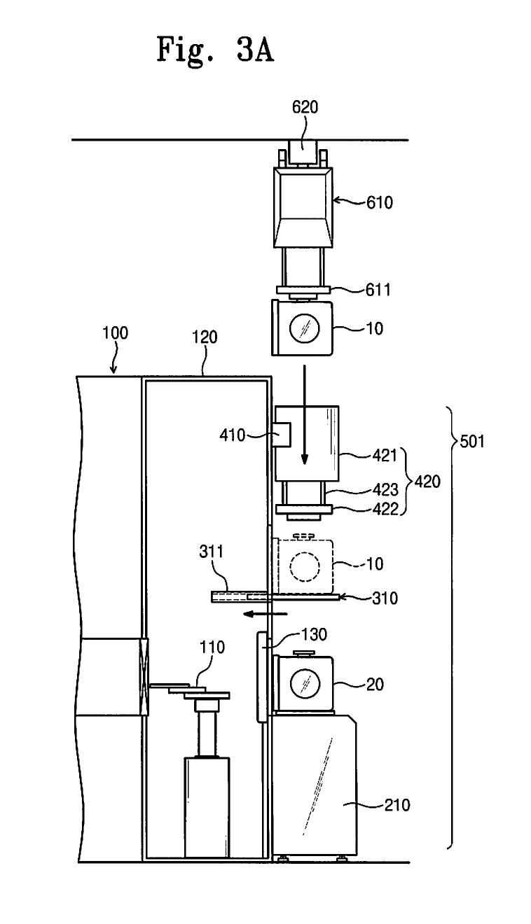

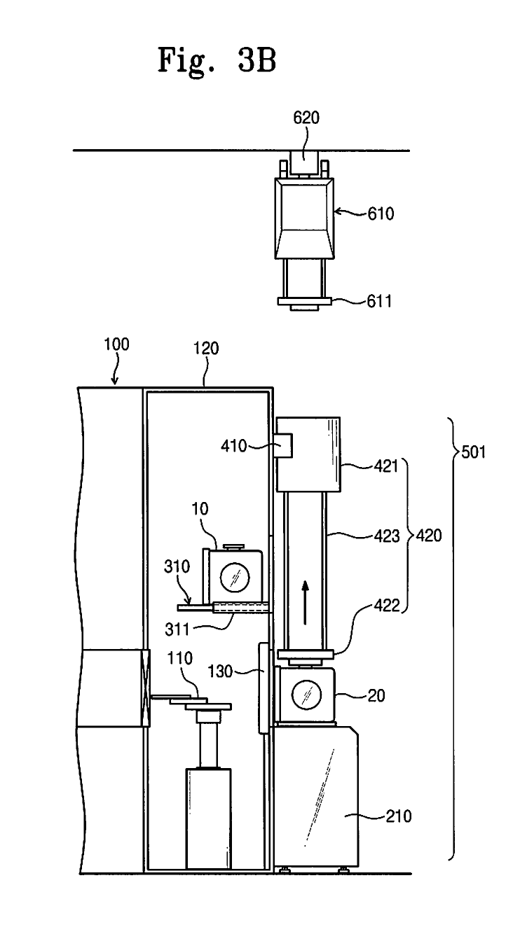

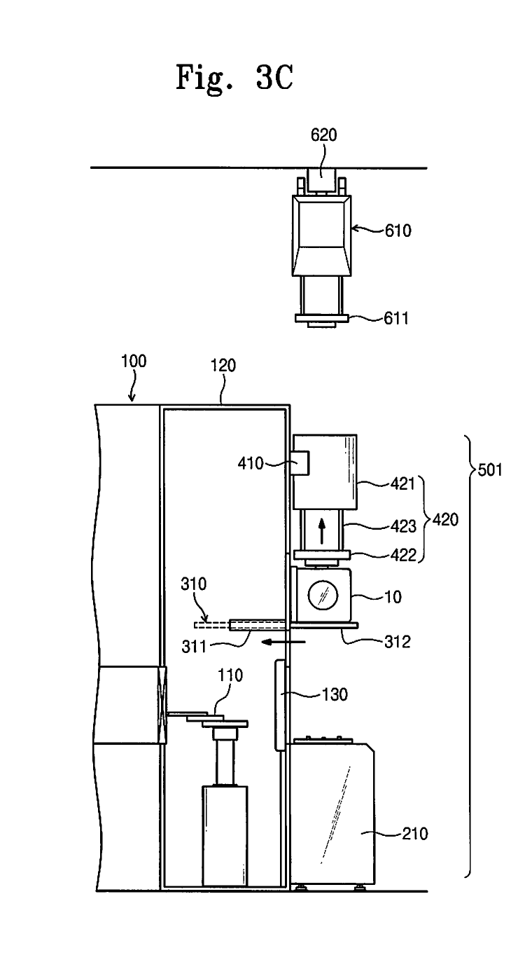

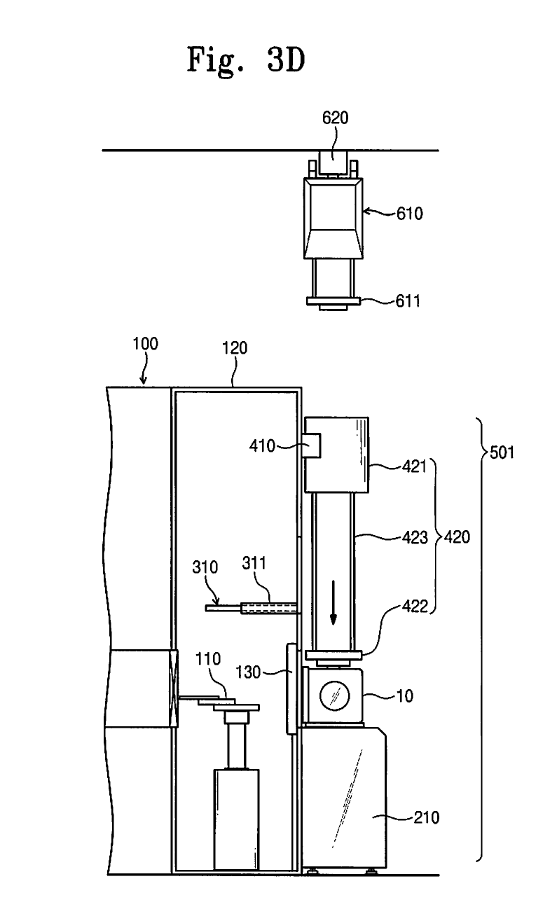

FIGS. 3A through 3D are views for explaining how substrates are transferred in the substrate processing apparatus 701 illustrated in FIG. 2.

Referring to FIG. 3A, the OHT 610 carries a FOUP 10 from an outside area to an empty buffer port of the first to fourth buffer ports 310 to 340 where no FOUP 10 is placed.

If the first buffer port 310 is empty as shown in FIG. 3A, the OHT 610 transfers a standby FOUP 10 to the first buffer port 310.

In the substrate processing apparatus 701, one of the first to fourth load ports 210 to 240 and the first to fourth buffer ports 310 to 340 is kept empty for smooth transfer of FOUPs 10. That is, in a state where FOUPs 10 are placed on all the first to fourth load ports 210 to 240 and the first to fourth buffer ports 310 to 340, although wafers accommodated in one of the FOUPs 10 placed on the first to fourth load ports 210 to 240 are completely processed, the FOUP 10 in which the processed wafers are accommodated cannot be transferred form the main load unit 200 to the buffer load unit 301 until one of the FOUPs 10 placed on the buffer load unit 301 and charged with processed wafers is transferred to an outside area. For this reason, one of the first to fourth load ports 210 to 240 and the first to fourth buffer ports 310 to 340 is kept empty.

Referring to FIG. 3B, if processed wafers are charged into a FOUP 10 placed on one of the first to fourth load ports 210 to 240, the distribution unit 401 picks up the FOUP 10 from the load port and places the FOUP 10 on an empty buffer port of the first to fourth buffer ports 310 to 340.

For example, if processed wafers are charged into a FOUP 10 placed on the first load port 210, the pickup part 420 of the distribution unit 401 is moved along the transfer rail 410 to a position over the first load port 210. At this time, the stages 312 of the first to fourth buffer ports 310 to 340 are slid into the process module 100 so as not to hinder the movement of the pickup part 420.

Next, the pickup part 420 picks up the FOUP 10 in which processed wafers are charged.

Referring to FIG. 3C, together with the FOUP 10, the pickup part 420 is moved along the transfer rail 410 toward an empty buffer port. For example, if the first buffer port 310 is empty, the pickup part 420 is moved toward the first buffer port 310 together with the FOUP 10.

Next, the stage 312 of the first buffer port 310 is moved out of the partition bay 120 to a position facing the first load port 210, and the pickup part 420 places the FOUP 10 on the first buffer port 310.

Thereafter, the FOUP 10 is picked up from the first buffer port 310 and transferred to an outside area by the OHT 610 moving along the equipment rail 620.

After the FOUP 10 in which processed wafers are accommodated is transferred from the first load port 210 to the first buffer port 310, the first load port 210 waits in an empty state.

Referring to FIG. 3D, the distribution unit 401 carries a standby FOUP 10 to the empty first load port 210. In detail, the distribution unit 401 picks up a standby FOUP 10 from one of the first to fourth buffer ports 310 to 340 and places the FOUP 10 on the empty first load port 210.

In this way, a FOUP 10 in which processed wafers are accommodated is not kept at the main load unit 200 but is transferred from the main load unit 200 to the buffer load unit 301 by the distribution unit 401. Then, the FOUP 10 is kept at the buffer load unit 301 until the FOUP 10 is transferred to an outside area by the OHT 610. Therefore, although the OHT 610 delays transfer of FOUPs 10 (in which processed wafers are accommodated) to an outside area, unprocessed wafers can be smoothly supplied to the process module 100 of the substrate processing apparatus 701, and thus process wait time can be reduced.

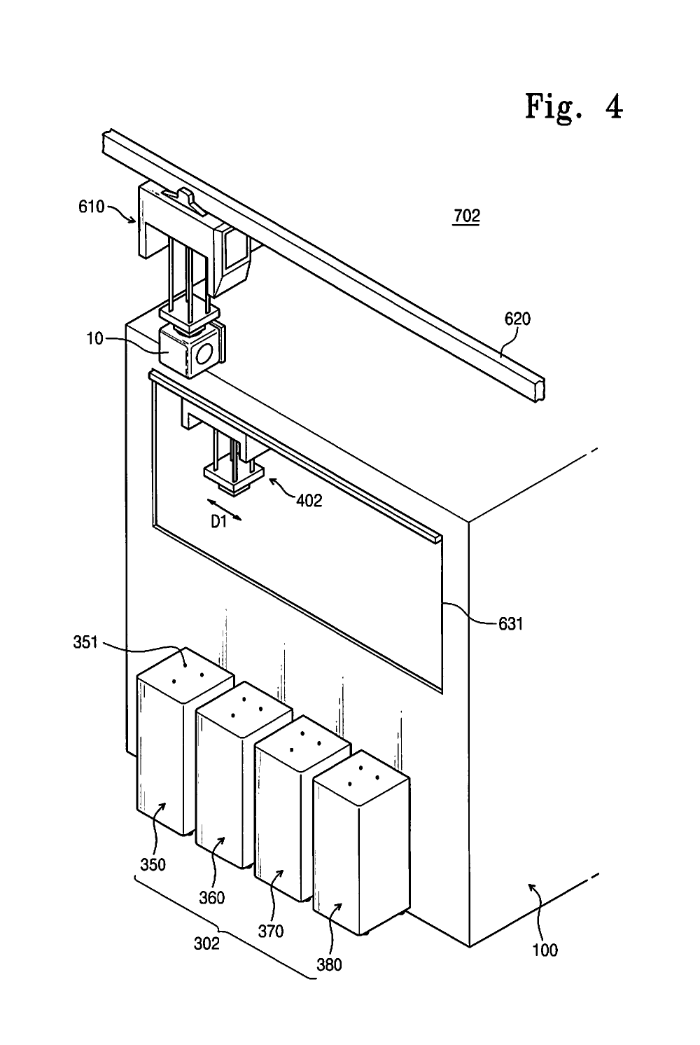

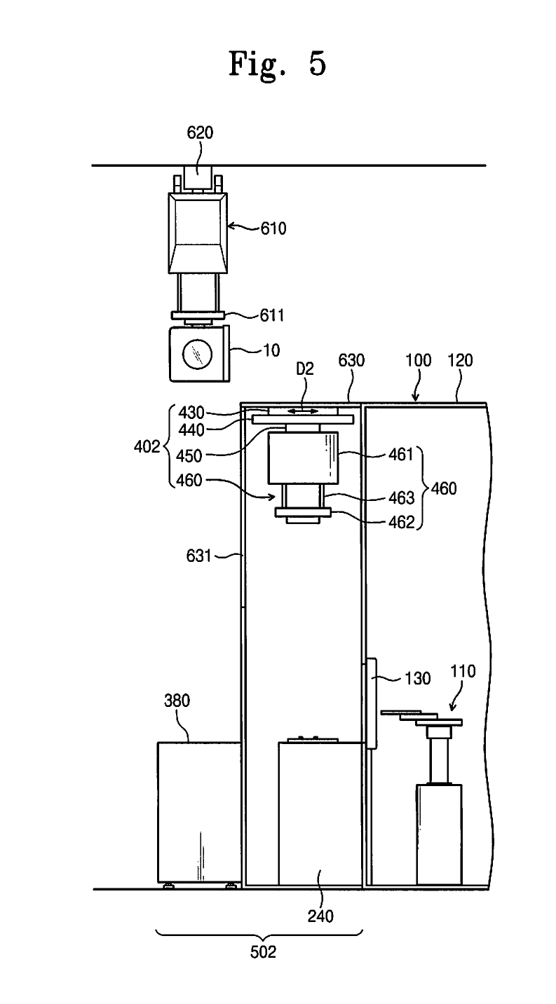

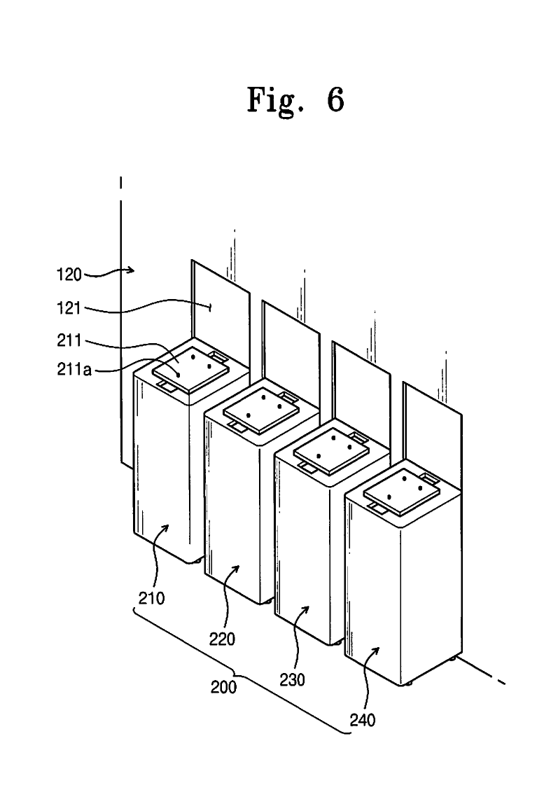

FIG. 4 is a partial perspective view illustrating a substrate processing apparatus 702 according to another embodiment of the present invention; FIG. 5 is a section view illustrating the substrate processing apparatus 702 illustrated in FIG. 5; and FIG. 6 is a partial perspective view illustrating a main load unit 200 of the substrate processing apparatus 702 illustrated in FIG. 5.

Referring to FIGS. 4 through 6, the substrate processing apparatus 702 of the current embodiment includes a process module 100 and a substrate supply module 502. The process module 100 is configured to process wafers, and the substrate supply module 502 is configured to supply wafers (unprocessed wafers) to the process module 100 for processing the wafers and carry the wafers to the outside after the wafers are processed.

In detail, unprocessed wafers are supplied to the substrate processing apparatus 702 in a state where the unprocessed wafers are accommodated in a FOUP 10, and after the unprocessed wafers are processed, the processed wafers are carried out of the substrate processing apparatus 702 in a state where the processed wafers are accommodated in the FOUP 10.

The process module 100 includes an index robot 110 configured to pick up unprocessed wafers from a FOUP 10 carried to the substrate supply module 502. Unprocessed wafers picked up by the index robot 110 are supplied to a plurality of process chambers (not shown) for processing the wafers. In the process chambers, a processing process such as a cleaning process may be performed. After the wafers are processed, the index robot 110 loads the processed wafers back to the FOUP 10 disposed at the substrate supply module 502. That is, after the wafers are processed, the wafers are carried out of the process chambers, and the index robot 110 transfers and loads the processed wafers back to the FOUP 10.

The substrate supply module 502 is disposed at the front side of the process module 100 for supplying wafers to the process module 100 in a state where the wafers are accommodated in the FOUP 10.

In detail, the substrate supply module 502 may include a main load unit 200, a buffer load unit 302, and a distribution unit 402.

The main load unit 200 is disposed at the front side of the process module 100 and makes contact with the process module 100. The main load unit 200 includes a plurality of load ports 210 to 240, and a FOUP 10 can be placed on each of the load ports 210 to 240. The first to fourth load ports 210 to 240 have the same structures as the first to fourth load ports 210 to 240 illustrated in FIG. 1, and thud descriptions thereof will be omitted.

The load ports 210 to 240 are disposed at a sidewall of a first partition bay 120 in which components of the process module 100 are disposed, and a plurality of door openers 130 corresponding to the load ports 210 to 240 are disposed at the first partition bay 120. The door openers 130 are used to open doors of FOUPs 10 placed on the corresponding load ports 210 to 240.

In the current embodiment, the main load unit 200 is disposed inside a second partition bay 630. The second partition bay 630 is disposed at a side of the first partition bay 120 to separate a region in which the main load unit 200 is disposed from the outside environments.

The buffer load unit 302 is disposed behind the main load unit 200. The buffer load unit 302 is disposed outside the second partition bay 630, and a plurality of FOUPs 10 can be placed on the buffer load unit 302.

In detail, the buffer load unit 302 includes a plurality of buffer ports 350 to 380. In an embodiment, the number of the buffer ports 350 to 380 is equal to the number of the load ports 210 to 240, and the positions of the buffer ports 350 to 380 correspond to the positions of the load ports 210 to 240, respectively. However, the number of the buffer ports 350 to 380 can be increased or decreased for the processing efficiency of the substrate processing apparatus 702.

The buffer ports 350 to 380 are arranged in the same direction as the load ports 210 to 240 in a manner such that the buffer ports 350 to 380 face the corresponding load ports 210 to 240, respectively. Each of the buffer ports 350 to 380 may include a plurality of protrusions 351 so that a FOUP 10 placed on the top surface of the buffer port can be fixed. The protrusions 351 extend from the top surfaces of the buffer ports 350 to 380 so that the protrusions can be coupled to FOUPs 10 placed on the top surfaces of the buffer ports 350 to 380 so as to fix the FOUPs 10 to the buffer ports 350 to 380.

The distribution unit 402 is disposed above the main load unit 200. The distribution unit 402 is disposed inside the second partition bay 630 for transferring a FOUP 10 between the buffer load unit 302 and the main load unit 200.

The distribution unit 402 is disposed above the main load unit 200. The distribution unit 402 is movable horizontally in a first direction D1 along which the fourth load port 240 are arranged and horizontally in a second direction D2 perpendicular to the first direction D1.

In detail, the distribution unit 402 includes a first transfer rail 430, a movable plate 440, a second transfer rail 450, and a pickup part 460. The first transfer rail 430 extends on the inner top surface of the second partition bay 630 in the second direction D2.

The movable plate 440 is coupled to the first transfer rail 430 for being moved along the first transfer rail 430 in the second direction D2 so that the movable plate 440 can be moved into and out of the second partition bay 630. The second transfer rail 450 is disposed at the bottom side of the movable plate 440. The second transfer rail 450 extends in the first direction D1. The pickup part 460 is coupled to the second transfer rail 450 so that the pickup part 460 can be moved along the second transfer rail 450 for picking up a FOUP 10.

The pickup part 460 may include a rail-movable part 461 coupled to the second transfer rail 450 for being moved along the second transfer rail 450, a fixer 462 configured to be detachably coupled to the top end of a FOUP 10 when the FOUP 10 is transferred, and a wire part 463 configured to adjust the vertical position of the fixer 422.

A side of the rail-movable part 461 is coupled to the second transfer rail 450, and the rail-movable part 461 is horizontally movable for adjusting the horizontal position of the fixer 462. That is, the rail-movable part 461 is moved along the second transfer rail 450 toward one of the load ports 210 to 240 and the buffer ports 350 to 380 where a FOUP 10 to be transferred is placed. Then, the pickup part 460 can be placed above the load port or buffer port. When the rail-movable part 461 is moved, the fixer 462 is kept at a predetermined height for preventing inference with FOUPs 10 placed on the main load unit 200.

An end of the wire part 463 is coupled to the fixer 462, and the other end of the wire part 463 is coupled to the rail-movable part 461. The length of the wire part 463 can be adjusted for lifting or lowering the fixer 462.

That is, when the pickup part 460 is placed above one of the load ports 210 to 240 and the buffer ports 350 to 380 on which a FOUP 10 to be transferred is placed, the fixer 462 is lowered by using the wire part 463 to place the fixer 462 on the top side of the FOUP 10. Then, the fixer 462 is coupled to the top side of the FOUP 10 for fixing the FOUP 10 to the pickup part 460. Thereafter, the fixer 462 is lifted by using the wire part 463 to a height where the FOUP 10 coupled to the fixer 462 does not make interference with other FOUPs 10 placed on the main load unit 200 or the buffer load unit 302.

After the FOUP 10 is fixed to the pickup part 460, the movable plate 440 is horizontally moved along the first transfer rail 430 from an upper region of the main load unit 200 to an upper region of the buffer load unit 302, or vice versa. At this time, the pickup part 460 and the FOUP 10 fixed to the pickup part 460 are moved into or out of the second partition bay 630 according to the movement of the movable plate 440. An inlet/outlet hole 631 is formed in a sidewall of the second partition bay 630 so that the movable plate 440, the pickup part 460, and the FOUP 10 fixed to the pickup part 460 can be moved through the sidewall of the second partition bay 630.

Thereafter, the rail-movable part 461 is moved along the second transfer rail 450 toward one of the load ports 210 to 240 and the buffer ports 350 to 380 for placing the FOUP 10 on the load port or the buffer port. Then, the fixer 462 is lowered by the wire part 463 to place the FOUP 10 to the load port or the buffer port.

In the current embodiment, the fixer 462 is configured to be detachably coupled to the top side of a FOUP 10. However, the fixer 462 can be configured to be detachably coupled to a lateral side of a FOUP 10. Furthermore, instead of adjusting the vertical position of the fixer 462 of the pickup part 460 by using a wire, the vertical position of the fixer 462 may be adjusted by using a vertically movable arm or rail.

An equipment rail 620 is disposed above the buffer load unit 302 so that the OHT 610 can be moved on the equipment rail 620. Generally, the equipment rail 620 may be installed on the ceiling of a semiconductor manufacturing line where the substrate processing apparatus 702 is disposed. While moving along the equipment rail 620, the OHT 610 receives a FOUP 10 from another area and places the FOUP 10 on one of the buffer ports 350 to 380. In addition, the OHT 610 picks up a FOUP 10 placed on one of the buffer ports 350 to 380 and transfers the FOUP 10 to another area.

As described above, the substrate processing apparatus 702 includes the buffer ports 350 to 380 as well as the load ports 210 to 240 for temporarily placing FOUPs 10 on the buffer ports 350 to 380 before the FOUPs 10 are transferred to a processing area. In addition, since the distribution unit 402 is used to transfer FOUPs 10 between the load ports 210 to 240 and the buffer ports 350 to 380, FOUPs 10 can be carried into and out of the substrate processing apparatus 702 with less influence by the transfer speed of the OHT 610.

Accordingly, the substrate processing apparatus 702 can have a reduced time for supplying FOUPs 10 to the process module 100 from a standby area. That is, equipment idle time can be reduced, and productivity can be improved.

Hereinafter, with reference to the accompanying drawings, detailed explains will be given on a process of transferring standby FOUPs in the substrate processing apparatus 702 and a process of transferring FOUPs to the outside of the substrate processing apparatus 702 after a processing process is finished. In the following explanations, the load ports 210 to 240 will be referred to as first to fourth load ports 210 to 240, and the buffer ports 350 to 380 will be referred to as first to fourth buffer ports 350 to 380. The first to fourth load ports 210 to 240 are sequentially arranged in the same direction, and the first to fourth buffer ports 350 to 380 are sequentially arranged in the same direction.

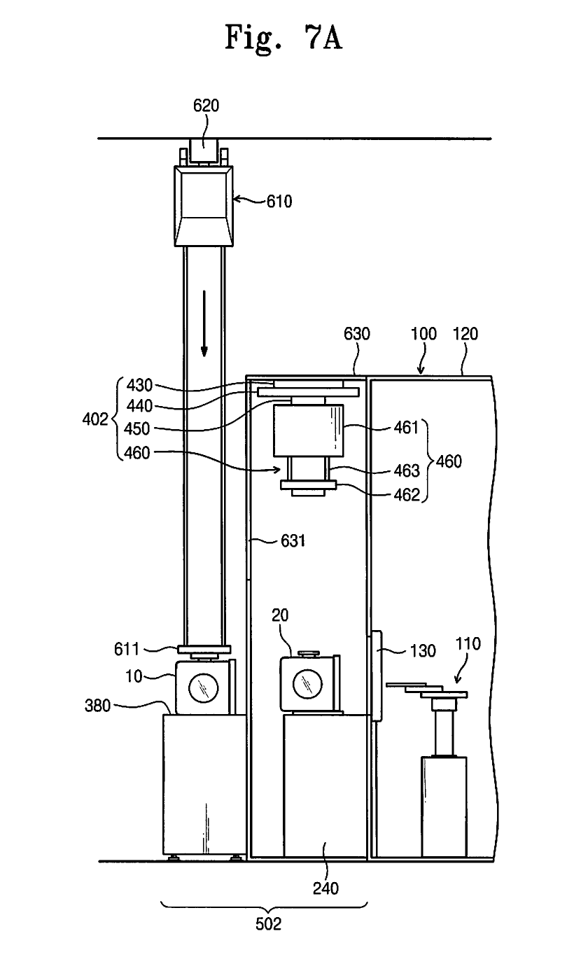

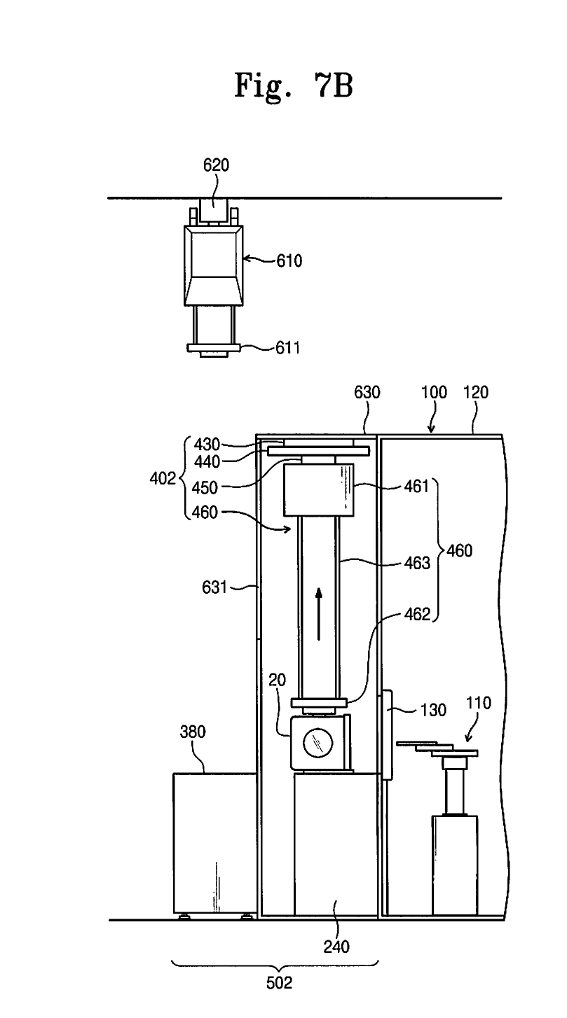

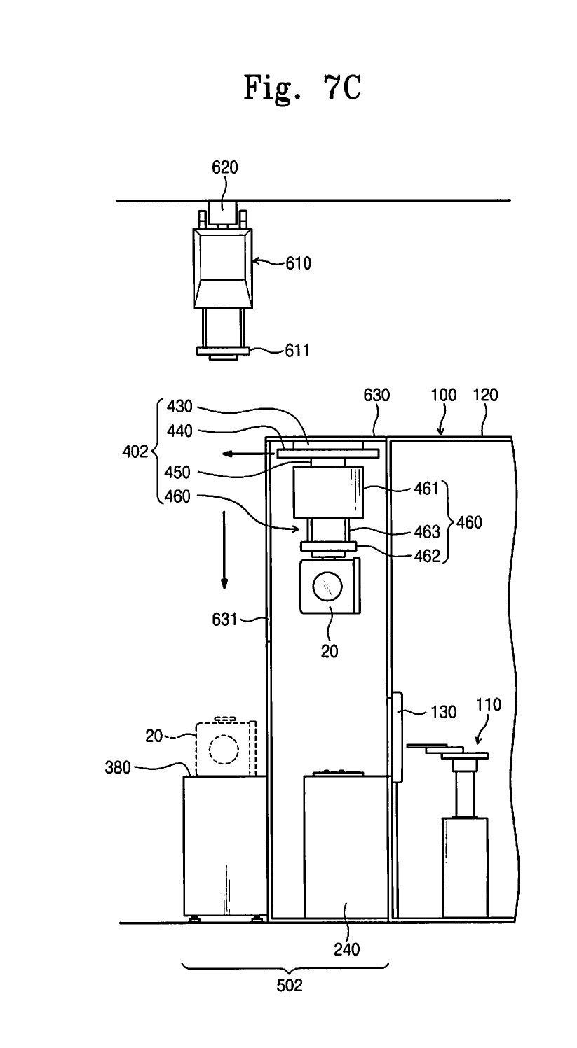

FIGS. 7A through 7C are views for explaining how substrates are transferred in the substrate processing apparatus 702 illustrated in FIG. 4.

Referring to FIG. 7A, the OHT 610 carries a FOUP 20 from an outside area to an empty buffer port of the first to fourth buffer ports 350 to 380 where no FOUP 20 is placed.

If the fourth buffer port 380 is empty as shown in FIG. 7A, the OHT 610 transfers a standby FOUP 20 to the fourth buffer port 380.

In the substrate processing apparatus 702, one of the first to fourth load ports 210 to 240 and the first to fourth buffer ports 350 to 380 is kept empty for smooth transfer of FOUPs 20.

Referring to FIG. 7B, if processed wafers are charged into a FOUP 20 placed on one of the first to fourth load ports 210 to 240, the distribution unit 402 picks up the FOUP 20 from the load port and places the FOUP 20 on an empty buffer port of the first to fourth buffer ports 350 to 380.

For example, if processed wafers are charged into a FOUP 20 placed on the fourth load port 240, the pickup part 460 of the distribution unit 402 is moved along the second transfer rail 450 to a position over the fourth load port 240 for picking up the FOUP 20 in which processed wafers are charged.

Referring to FIG. 7C, the distribution unit 402 transfers the FOUP 20 in which processed wafers are charged to an empty buffer port of the first to fourth buffer ports 350 to 380. In detail, first, the movable plate 440 is moved along the first transfer rail 430 to the outside of the second partition bay 630 through the inlet/outlet hole 631. Thus, the pickup part 460 is placed above the buffer load unit 302.

Next, the pickup part 460 is moved along the second transfer rail 450 toward an empty buffer port of the first to fourth buffer ports 350 to 38 to place the standby FOUP 20 on the empty buffer port. For example, if the fourth buffer port 380 of the first to fourth buffer ports 350 to 380 is empty, the pickup part 460 places the FOUP 20 (picked up from the main load unit 200) on the fourth buffer port 380.

In this way, the FOUP 20 in which processed wafers are charged is transferred to the buffer load unit 302. Then, the FOUP 20 is carried to the outside by the OHT 610.

After the FOUP 20 in which processed wafers are charged is transferred from the fourth load port 240 to the buffer load unit 302, the fourth load port 240 waits in an empty state. The pickup part 460 of the distribution unit 402 picks up a standby FOUP 20 from the buffer load unit 302, and the movable plate 440 is moved along the first transfer rail 430 into the second partition bay 630. Then, the pickup part 460 is placed above the main load unit 200. Next, the pickup part 460 is moved along the second transfer rail 450 to a position above the fourth load port 240 to place the standby FOUP 20 on the fourth load port 240.

As described above, the substrate processing apparatus includes the buffer ports capable of receiving containers as well as the load ports, so that standby containers can be transferred to the load ports with less time. Therefore, substrates can be transferred to the substrate processing apparatus with less time, and thus productivity can be improved.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A substrate processing apparatus comprising:
a process module configured to process a substrate;
a main load unit disposed at a front side of the process module for receiving a plurality of containers each accommodating a plurality of substrates, the main load unit being configured so that substrates are transferred between the containers placed on the main load unit and the process module;
a buffer load unit configured to receive a plurality of containers; and
a distribution unit disposed above the main load unit for transferring a container between the main load unit and the buffer load unit.

2. The substrate processing apparatus of claim 1, wherein the main load unit comprises a plurality of load ports configured to receive containers respectively and disposed at the front side of the process module in parallel with each other, and
the buffer load unit comprises a plurality of buffer ports configured to receive containers, each of the buffer ports facing one of the load ports.

3. The substrate processing apparatus of claim 2, wherein the buffer ports are disposed above the main load unit and horizontally movable into and out of the process module.

4. The substrate processing apparatus of claim 3, wherein the buffer ports of the buffer load unit are movable horizontally and independently.

5. The substrate processing apparatus of claim 4, wherein each of the buffer ports comprises:
a guide rail disposed in the process module; and
a stage configured to receive a container and couple with the guide rail for moving horizontally along the guide rail.

6. The substrate processing apparatus of claim 4, wherein the distribution unit is disposed above the buffer ports and configured to move horizontally in a direction along which the load ports are arranged, so as to transfer a container.

7. The substrate processing apparatus of claim 6, wherein the distribution unit comprises:
a transfer rail extending in the direction where the load ports are arranged; and
a pickup part configured to pick up a container from one of the load and buffer ports and move along the transfer rail.

8. The substrate processing apparatus of claim 2, wherein the buffer ports face the process module with the load ports being disposed between the buffer ports and the process module.

9. The substrate processing apparatus of claim 8, wherein the distribution unit which is disposed above the main load unit and is horizontally movable in a first direction along which the load parts are arranged, the distribution unit is horizontally movable above the main load unit and the buffer load unit in a second direction perpendicular to the first direction.

10. The substrate processing apparatus of claim 9, wherein the distribution unit comprises:
a first movable part configured to move horizontally in the second direction;
a second movable part disposed under the first movable part and coupled to the first movable part, the second movable part being configured to move horizontally in the first direction; and
a pickup part disposed under the second movable part and coupled to the second movable part, the pickup part being configured to pick up a container and move vertically.

11. The substrate processing apparatus of claim 2, further comprising an overhead hoist transport unit configured to transfer a container between an outside area and the buffer load unit.

12. A substrate processing apparatus comprising:
a process module configured to process a substrate;
a plurality of load ports disposed at a front side of the process module in parallel with each other for receiving containers each accommodating substrates, the load ports being configured so that substrates are transferred between the containers placed on the load ports and the process module;
a plurality of buffer ports disposed directly above the load ports, each of the buffer ports facing one of the load ports and configured to receive a container and move horizontally into and out of the process module;
a distribution unit disposed above the buffer ports and movable horizontally in a direction along which the load ports are arranged, so as to transfer a container between the buffer ports and the load ports; and
an overhead hoist transport unit configured to transfer a container between an outside area and the buffer ports.

13. A substrate processing apparatus comprising:
a process module configured to process a substrate;
a plurality of load ports disposed at a front side of the process module in parallel with each other for receiving containers each accommodating substrates, the load ports being configured so that substrates are transferred between the containers placed on the load ports and the process module;
a plurality of buffer ports facing the process module with the load ports being disposed between the buffer ports and the process module, each of the buffer ports facing one of the load ports and configured to receive a container;
a distribution unit disposed above the load ports, the distribution unit being configured to move horizontally in a first direction along which the load ports are arranged and move horizontally above the load ports and the buffer ports in a second direction perpendicular to the first direction, so as to transfer a container between the buffer ports and the load ports; and
an overhead hoist transport unit configured to transfer a container between an outside area and the buffer ports.

14. A method for transferring a substrate, comprising:
transferring a container accommodating unprocessed substrates from an outside area to an empty buffer port of a plurality of buffer ports;
picking up a container accommodating unprocessed substrates from the buffer ports and placing the container on an empty load port of a plurality of load ports so as to load the unprocessed substrates contained in the container to a process module for processing the unprocessed substrates; and
picking up a container accommodating processed substrates from the load ports and transferring the container to an empty buffer port of the buffer ports,
wherein a distribution unit disposed above the load ports is used to transfer a container between the buffer ports and the load ports, and
an overhead hoist transport unit is used to transfer a container accommodating unprocessed substrates from the outside area to an empty buffer port of the buffer ports and transfer a container accommodating processed substrates to the outside area.

15. The method of claim 14, wherein the buffer ports are disposed directly above the load ports and configured to move horizontally into or out of the process module when a container is transferred between the buffer ports and the load ports by the distribution unit, and
the distribution unit disposed above the buffer ports is moved toward one of the buffer ports or the load ports in a direction along which the load ports are arranged, so as to transfer a container between the buffer ports and the load ports.

16. The method of claim 14, wherein the buffer ports face the process module with the load ports being disposed between the buffer ports and the process module, and
a container is transferred between the buffer ports and the load ports by moving the distribution unit in a first direction along which the load ports are arranged and in a second direction perpendicular to the first direction.

17. A method for transferring a substrate, comprising:
transferring a container accommodating unprocessed substrates from an outside area to a buffer load unit;
transferring a container accommodating unprocessed substrates from the buffer load unit to a main load unit so as to load the unprocessed substrates contained in the container to a process module for processing the substrates;
transferring a container accommodating processed substrates from the main load unit to the buffer load unit; and
transferring a container accommodating processed substrates from the buffer load unit to the outside area.

18. The method of claim 17, wherein a distribution unit disposed above the load ports is used to transfer a container between the buffer load unit and the main load unit, and
an overhead hoist transport unit is used to transfer a container accommodating unprocessed substrates from the outside area to the buffer load unit and transfer a container accommodating processed substrates to the outside area.
